(19) United States
(12) Patent Application Publication
(10) Pub. No.: US 2024/0191345 A1
(43) Pub. Date: Jun. 13, 2024

(54) COMPONENT FOR SEMICONDUCTOR PRODUCTION APPARATUS AND METHOD FOR PRODUCING SUCH COMPONENT

(71) Applicant: AGC Inc., Tokyo (JP)

(72) Inventors: Rui HAYASHI, Tokyo (JP); Tomonori OGAWA, Tokyo (JP); Koji KAWAHARA, Tokyo (JP)

(73) Assignee: AGC Inc., Tokyo (JP)

(21) Appl. No.: 18/411,398

(22) Filed: Jan. 12, 2024

Related U.S. Application Data
(63) Continuation of application No. PCT/JP2022/028809, filed on Jul. 26, 2022.

(30) Foreign Application Priority Data
Jul. 30, 2021 (JP) 2021-125188
Sep. 30, 2021 (JP) 2021-160559
Apr. 11, 2022 (JP) 2022-065313

(51) Int. Cl. C23C 16/32

(52) U.S. Cl. CPC C23C 16/325

(57) ABSTRACT

A component for a semiconductor production apparatus includes a part of polycrystalline silicon carbide (SiC) produced through chemical vapor deposition (CVD), the part being of the component. The part of the polycrystalline SiC includes a first dopant with which the part of the polycrystalline SiC is doped in a range of from 10 atomic concentration in ppm through 10 atomic concentration in % with respect to an entirety of the part. The first dopant includes at least one element selected from the group consisting of aluminum (Al), yttrium (Y), magnesium (Mg), tin (Sn), calcium (Ca), zinc (Zn), cobalt (Co), iron (Fe), nickel (Ni), silver (Ag), and chromium (Cr).

### CROSS-REFERENCE TO RELATED APPLICATION

The present application is a continuation application of International Application No. PCT/JP2022/028809 filed on Jul. 26, 2022, and designated the U.S., which is based upon and claims priority to Japanese Patent Application No. 2021-125188 filed on Jul. 30, 2021, Japanese Patent Application No. 2021-160559 filed on Sep. 30, 2021, and Japanese Patent Application No. 2022-065313 filed on Apr. 11, 2022, the entire contents of which are incorporated herein by reference.

### BACKGROUND

### 1. Field of the Invention

The present disclosure relates to components for semiconductor production apparatuses and methods for producing such components.

### 2. Description of the Related Art

Semiconductor production apparatuses often use components including silicon carbide (SiC).

For example, plasma etching apparatuses include various components such as an edge ring, an electrostatic chuck, a shower plate, and the like. These components include a substrate and a SiC film on the substrate. Alternatively, these components may include the SiC film alone.

For example, Japanese Laid-Open Patent Publication No. 2000-199063 describes a method of producing a ring component by forming a SiC film on a carbon substrate through thermal chemical vapor deposition (CVD).

### SUMMARY

A component for a semiconductor production apparatus (hereinafter may be referred to as a “semiconductor production apparatus component”) of the present disclosure includes a part of polycrystalline silicon carbide (SiC) produced through chemical vapor deposition (CVD), the part being of the component. The part of the polycrystalline SiC includes a first dopant with which the part of the polycrystalline SiC is doped in a range of from 10 atomic concentration in ppm through 10 atomic concentration in % with respect to an entirety of the part. The first dopant includes at least one element selected from the group consisting of aluminum (Al), yttrium (Y), magnesium (Mg), tin (Sn), calcium (Ca), zinc (Zn), cobalt (Co), iron (Fe), nickel (Ni), silver (Ag), and chromium (Cr).

Also, a method for producing a semiconductor production apparatus component of the present disclosure includes supplying a gas mixture to a surface of a substrate, the gas mixture including a Si source gas, a C source gas, and a source gas for a first dopant, thereby forming a film of polycrystalline SiC through chemical vapor deposition (CVD), the film of the polycrystalline SiC being doped with the first dopant in a range of from 10 atomic concentration in ppm through 10 atomic concentration in %. The first dopant includes at least one element selected from the group consisting of aluminum (Al), yttrium (Y), magnesium (Mg), tin (Sn), calcium (Ca), zinc (Zn), cobalt (Co), iron (Fe), nickel (Ni), silver (Ag), and chromium (Cr).

### BRIEF DESCRIPTION OF DRAWINGS

FIG. 1 is a view schematically illustrating a cross section of one example of a plasma etching apparatus.

FIG. 2 is a flowchart schematically illustrating one example of a method for producing a semiconductor production apparatus component according to one embodiment of the present disclosure.

### DESCRIPTION OF THE EMBODIMENTS

Components for semiconductor production apparatuses are often exposed to a plasma during transportation of the apparatuses. In such an environment in which the semiconductor production apparatuses are exposed to the plasma, components of SiC can be gradually worn. The components in which wearing has progressed in some degree are replaced with new ones.

Especially, in accordance with increasing in the number of stacked layers and complexity in products obtained by the recent semiconductor production processes, a plasma environment to which the components are exposed has been becoming more severe. As a result, there is a need to replace the components relatively frequently.

During replacement of the components, however, semiconductor production apparatuses cannot be driven. An increased frequency of such replacement leads to reduction in productivity. From this point of view, further improvement in service life of the components for the semiconductor production apparatuses is desired.

The present disclosure has been made in view of such a background, and it is an objective of the present disclosure to provide a semiconductor production apparatus component having plasma resistance that is significantly higher than the plasma resistance of existing components. Also, it is another objective of the present disclosure to provide a method for producing such a component.

Hereinafter, one embodiment of the present disclosure will be described.

According to one embodiment of the present disclosure, the semiconductor production apparatus component including the part of the polycrystalline SiC produced through CVD is provided. The part of the polycrystalline SiC includes the first dopant with which the part of the polycrystalline SiC is doped in the range of from 10 atomic concentration in ppm through 10 atomic concentration in % with respect to the entirety of the part. The first dopant includes at least one element selected from the group consisting of aluminum (Al), yttrium (Y), magnesium (Mg), tin (Sn), calcium (Ca), zinc (Zn), cobalt (Co), iron (Fe), nickel (Ni), silver (Ag), and chromium (Cr).

The semiconductor production apparatus component according to one embodiment of the present disclosure (hereinafter referred to simply as a “component according to one embodiment of the present disclosure”) includes a SiC part. The SiC part includes the polycrystalline SiC produced through CVD.

SiC components are widely used in fields other than in semiconductor production apparatuses. Usually, such SiC components are provided as sintered bodies obtained by sintering particulate materials. It is, however, hard to use such sintered bodies as components for semiconductor production apparatuses. This is because some of the particles forming the sintered bodies tend to drop. That is, when the SiC components that are sintered bodies are used for semiconductor production apparatuses, particles dropped from the components can be a cause for contamination.

Meanwhile, the component according to one embodiment of the present disclosure includes the polycrystalline SiC produced through CVD. Therefore, the component according to one embodiment of the present disclosure can be used as a component for semiconductor production apparatuses that require a high degree of cleanliness.

Note that, the polycrystalline SiC produced through CVD includes columnar silicon carbide crystals in which crystals are grown along a direction orthogonal to the substrate. Therefore, the polycrystalline SiC produced through CVD and the sintered body SiC can be distinguished by observing fine structures of cross sections thereof under a scanning electron microscope (SEM) or the like.

As described above, nowadays, semiconductor production apparatuses, e.g., plasma etching apparatuses require relatively frequent replacement of SiC components. Also, reduction in productivity due to such replacement of components has been an issue.

However, the SiC part included in the component according to one embodiment of the present disclosure is doped with the first dopant. The first dopant is selected from the group consisting of Al, Y, Mg, Sn, Ca, Zn, Co, Fe, Ni, Ag, Cr, and any combination thereof.

The first dopant is included in total in a range of from 10 atomic concentration in ppm through 30 atomic concentration in % with respect to the entirety of the SiC part.

As described below in detail, the component including the SiC part doped with the above first dopant can be significantly increased in plasma resistance.

Therefore, when the component according to one embodiment of the present disclosure is used in semiconductor production apparatuses, the frequency of replacement of the component is reduced, and the productivity can be increased.

### (Effects of the First Dopant)

As described above, the component according to one embodiment of the present disclosure has high plasma resistance. The following is a conceivable reason for this.

Usually, a plasma used in plasma etching apparatuses includes a fluoride. When the SiC film is exposed to the plasma including the fluoride, reaction occurs on the surface of the film, thereby producing fluorides of silicon (e.g., SiF₄) and fluorides of carbon (e.g., CF₄).

All of these reaction products have a boiling point of 0° C. or lower. For example, the boiling point of SiF₄ is −86° C. Also, the boiling point of CF₄ is −184° C. Therefore, the fluorides of silicon and the fluorides of carbon, which are produced on the surface of the film, rapidly vaporize and do not remain on the surface. During the exposure of the SiC film to the plasma, the reaction of producing the fluoride and the vaporization of the fluoride continue. As a result, the SiC film is considered to be corroded relatively rapidly.

Meanwhile, in one embodiment of the present disclosure, all of the fluorides of the first dopant, which can be included in the SiC part, have a higher boiling point. For reference, Table 1 below shows boiling points of the fluorides of metals that can be the first dopant.

TABLE 1

| Fluorides | Boiling point (° C.) |
|---|---|
| AlF₃ | 1291 |
| YF₃ | 2230 |
| SnF₄ | 705 |
| CaF₂ | 2533 |
| ZnF₂ | 1497 |
| CoF₂ | 1400 |
| FeF₃ | 1100 |
| NiF₂ | 1000 |
| AgF | 1150 |
| CrF₃ | 1100 |

As shown in Table 1, all of the boiling points of the fluorides shown are higher than 700° C.

Therefore, in one embodiment of the present disclosure, when fluorides of the first dopant are produced in the SiC part including the first dopant by exposure to the plasma, such fluorides remain on the surface of the SiC film. The fluorides remaining on the surface thereof can protect the SiC part from corrosion that can be subsequently caused by the plasma.

As the result of the above-described effects, the first dopant-doped SiC part in the component according to one embodiment of the present disclosure is considered to have increased plasma resistance.

Note that, in order to obtain the above-described effects, the SiC part is doped with the first dopant at 10 atomic concentration in ppm or more with respect to the entirety of the SiC part. With respect to the entirety of the SiC part, the SiC part is preferably doped with the first dopant at 50 atomic concentration in ppm or more, more preferably 100 atomic concentration in ppm or more, still more preferably 300 atomic concentration in ppm or more, and even more preferably 500 atomic concentration in ppm or more. Especially, with respect to the entirety of the SiC part, the SiC part is preferably doped with the first dopant at 0.1 atomic concentration in % or more, more preferably 1 atomic concentration in % or more, still more preferably 5 atomic concentration in % or more, and even more preferably more than 10 atomic concentration in %.

Meanwhile, when the SiC part is doped with an excessive amount of the first dopant, the above-described effects may be gradually lost. Therefore, with respect to the entirety of the SiC part, the SiC part is preferably doped with the first dopant at 30 atomic concentration in % or less, more preferably 25 atomic concentration in % or less, still more preferably 20 atomic concentration in % or less, and even more preferably 15 atomic concentration in % or less.

An excessive amount of the first dopant with which the SiC part is doped can be a cause for contamination. Therefore, the amount of the first dopant with which the SiC part is doped is limited to 10 atomic concentration in % or less with respect to the entirety of the SiC part. With respect to the entirety of the SiC part, the amount of the first dopant with which the SiC part is doped is preferably 5 atomic concentration in % or less, more preferably 1 atomic concentration in % or less, still more preferably 0.9 atomic concentration in % or less, even more preferably 0.5 atomic concentration in % or less, and particularly preferably 0.2 atomic concentration in % or less.

However, when a material used for a component in a plasma etching apparatus chamber including the component according to one embodiment of the present disclosure is the same as the first dopant, probability of occurrence of contamination is low during etching of the component according to one embodiment of the present disclosure. In such a case, doping of an excessive amount of the first dopant tends not to be an issue.

Note that, of the above-listed elements for the first dopant, Al is particularly preferable for the following reason. Specifically, when SiC is doped with a third element that is different from Si and C, substitution between the third element and Si or C in SiC crystals is considered to occur. Therefore, the atomic radius of the third element is desirably closer to the atomic radius of Si or C. In this regard, the atomic radius of Al is close to the atomic radius of Si (the atomic radius of Al is 1.18 angstroms and the atomic radius of Si is 1.11 angstroms) and Al can substitute Si or C without breaking the crystal structure of SiC. Therefore, SiC is relatively readily doped with Al, and it is expected that the effect of increasing the plasma resistance is readily obtained.

Al is also suitable when the plasma used in the plasma etching apparatuses includes other gases in addition to the fluorides. Typical examples of the other gases include argon (Ar), oxygen, and the like. A reason for this is as follows.

When the plasma includes Ar, an Ar plasma usually performs etching through physical corrosion. Therefore, the plasma resistance of a component is related to the strength of atomic bonds. Here, when Si is substituted with Al, the interatomic bonding force in the crystal structure increases. This is because the atomic radius of Al is larger than the atomic radius of Si, and thus the interatomic distance in the crystal structure becomes shorter. Therefore, the Al-doped SiC part is considered to have high plasma resistance to not only the fluorides but also Ar.

When the plasma includes oxygen, oxidation reaction occurs on the surface of the SiC film. Here, Al is usually readily oxidized compared to Si or C, and on the surface of the SiC film, an oxide of Al (alumina) is produced preferentially to an oxide of Si or C. As a result, the Al concentration on the surface of the SiC film gradually increases. Thereby, the above-described effect obtained by production of the fluoride of Al is considered to further significantly develop.

### (Other Features of the Component According to One Embodiment of the Present Disclosure)

Next, other features of the component according to one embodiment of the present disclosure will be described.

With respect to the volume of the entirety of the component according to one embodiment of the present disclosure, the percentage of the volume of the polycrystalline SiC produced through CVD is preferably 10% or more, more preferably 30% or more, still more preferably 50% or more, even more preferably 80% or more, particularly preferably 98% or more, and most preferably 99.5% or more.

Also, the SiC part in the component according to one embodiment of the present disclosure may be further doped with a second dopant.

The second dopant may include boron (B), nitrogen (N), or both.

The amount of the second dopant with which the SiC part is doped is, for example, in a range of from 10 atomic concentration in ppm through 10 atomic concentration in % with respect to the entirety of the SiC part. With respect to the entirety of the SiC part, the amount of the second dopant with which the SiC part is doped is preferably in a range of from 50 atomic concentration in ppm through 8 atomic concentration in %, more preferably in a range of from 100 atomic concentration in ppm through 6 atomic concentration in %, and still more preferably in a range of from 150 atomic concentration in ppm through 4 atomic concentration in %.

By doping the SiC part with the second dopant, it is possible to adjust the electrical resistivity of the component according to one embodiment of the present disclosure to a desired range.

The electrical resistivity of the component according to one embodiment of the present disclosure is adjustable, for example, in a range of from 0.01 Ωcm through 30,000 Ωcm, and especially in a range of from 0.02 Ωcm through 10,000 Ωcm.

Note that, the electrical resistivity is a key property in applying the component according to one embodiment of the present disclosure as, for example, a component for a semiconductor production apparatus. For example, when the component according to one embodiment of the present disclosure is used as an edge ring, it is desired that the electrical resistivity thereof be low for uniformity of the plasma. Also, for example, when the component according to one embodiment of the present disclosure is used as an electrostatic chuck, it is desired that the electrical resistivity thereof be high.

The component according to one embodiment of the present disclosure may include a substrate, and the SiC part may be provided as a film on the substrate. In this case, the thickness of the SiC film may be, for example, in a range of from 50 μm through 15 mm.

No particular limitation is imposed on a material of the substrate as long as the material thereof has heat resistance and plasma resistance.

However, the substrate preferably includes a material having a coefficient of linear thermal expansion that is close to the coefficient of linear thermal expansion of SiC. In this case, it is possible to form a high-quality SiC film with less cracks, bubbles, and the like on the substrate through CVD.

The substrate may include graphite, silicon, silicon carbide, a SiC—Si composite material, or the like.

Note that, in one embodiment of the present disclosure, the substrate is not an essential component, and the substrate may be omitted. In this case, the component according to one embodiment of the present disclosure may consist of the SiC part that is in a range of from 50 μm through 15 mm in thickness.

The component according to one embodiment of the present disclosure is applicable in semiconductor production apparatuses, especially, plasma etching apparatuses.

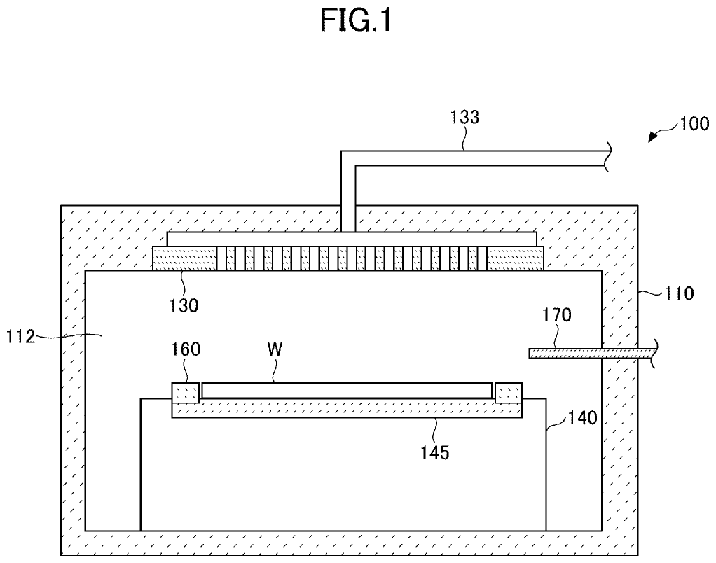

FIG. 1 is a view schematically illustrating a cross section of a plasma etching apparatus.

As illustrated in FIG. 1, a plasma etching apparatus 100 includes a chamber 110 having an internal space 112. A wafer W to be processed is disposed in the internal space 112.

A shower head 130 is provided in an upper part of the chamber 110. The shower head 130 has a plurality of gas discharge holes. Gas supplied from a supply tube 133 is supplied to the internal space 112 via the shower head 130.

At the bottom of the chamber 110, a stage 140 on which the wafer W is to be placed, is provided. Also, an electrostatic chuck 145 is provided on the stage 140. The electrostatic chuck 145 is configured to generate an electrostatic attractive force with, for example, unillustrated various voltage application apparatuses. Therefore, the wafer W is fixed at a predetermined position by the action of the electrostatic attractive force from the electrostatic chuck 145.

Also, an edge ring 160 is disposed on the stage 140 so as to surround the wafer W. The edge ring 160 has a doughnut shape, and plays a role in increasing in-plane uniformity of the plasma treatment to the wafer W.

Also, one or more sensors 170 configured to measure the temperature, the pressure, and the like of the internal space 112 are disposed in the chamber 110. Usually, a protective cover is provided around the sensor 170.

With the plasma etching apparatus 100, a plasma is generated in the internal space 112 from the gas supplied from the supply tube 133, and the wafer W can be treated with the generated plasma.

In the plasma etching apparatus 100, the shower head 130, the electrostatic chuck 145, the edge ring 160, and the protective cover of the sensor 170 are exposed to the plasma during the etching treatment of the wafer W. Therefore, corrosion of these components progresses as the plasma etching apparatus 100 is driven, and replacement thereof is needed after use for a certain period of time.

However, when the component according to one embodiment of the present disclosure is applied as components for the shower head 130, the electrostatic chuck 145, the edge ring 160, and the protective cover of the sensor 170, the plasma resistance thereof can be increased.

Therefore, with the plasma etching apparatus 100, it is possible to reduce the frequency of replacement of components, and increase productivity.

### (Method for Producing the Component According to One Embodiment of the Present Disclosure)

Next, a method for producing the component according to one embodiment of the present disclosure will be described.

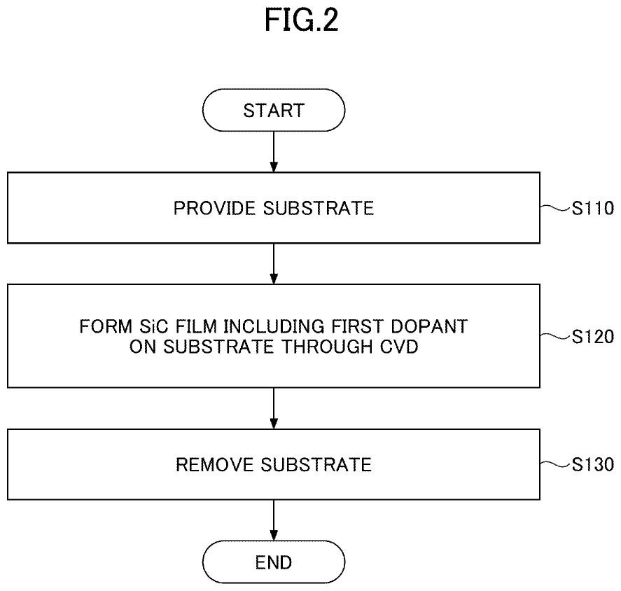

FIG. 2 is a flowchart schematically illustrating one example of the method for producing the component according to one embodiment of the present disclosure.

As illustrated in FIG. 2, the method for producing the component according to one embodiment of the present disclosure (hereinafter referred to as a “first production method”) includes (I) a step of providing a substrate (step S110), (II) a step of forming a SiC film including the first dopant on the substrate through CVD (step S120), and (III) a step of removing the substrate (step S130).

Note that, step S130 is not an essential step and may be omitted.

In the following, each of the steps will be described in more detail.

### (Step S110)

First, a substrate on which a SiC film is to be formed, is provided.

The substrate includes a material having heat resistance. The substrate may include graphite, silicon, a SiC—Si composite material, or the like.

However, when the substrate is removed in step S130 that is performed subsequently, no particular limitation is imposed on the material of the substrate as long as the material thereof exhibits resistance in step S120 that is performed next.

No particular limitation is imposed on the shape of the substrate. However, the shape of the substrate is preferably defined based on the final shape of the component. For example, when an edge ring is produced by the first production method, the substrate may have a ring shape.

### (Step S120)

Next, a SiC film is formed on the substrate through CVD.

For CVD, the internal pressure of the chamber is adjusted to 30 Pa or lower by, for example, a vacuum pump connected to the chamber in which the substrate is housed. Subsequently, in a state in which the interior of the chamber, the substrate, or both is heated to a predetermined temperature, a raw material gas is supplied into the chamber.

The raw material gas includes a Si source gas, a C source gas, and a source gas for the first dopant. If necessary, the raw material gas may further include a source gas for the second dopant.

Note that, the raw material gas may be mixed with a carrier gas and then supplied.

The Si source may be selected from SiCl₄, SiHCl₃, SiH₂Cl₂, SiH₄, and the like.

The C source may be selected from CH₄, C₂H₆, C₃H₈, and the like.

The Si source and the C source may be a single gas. For example, CH₃SiCl₃, (CH₃)₂SiCl₂, (CH₃)₃SiCl, and CVD-4000 (available from Starfire Systems) can be used as both of the Si source and the C source. Note that, CVD-4000 is gas including a [SiH₂—CH₂]ₙ bond.

As described above, the first dopant includes at least one element selected from the group consisting of Al, Y, Mg, Sn, Ca, Zn, Co, Fe, Ni, Ag, and Cr. For example, when the first dopant is Al, the source for the first dopant may be a halide of aluminum (e.g., AlCl₃), an organic aluminum compound (e.g., Al(CH₃)₃), or a mixture thereof. Likewise, when the first dopant is the element other than Al, a halide thereof, an organic compound thereof, or both can be used.

As described above, the second dopant is B, N, or both. When the source for the second dopant is B, a halide of boron (e.g., BCl₃), an organic boron compound, or both may be used. When the second dopant is N, ammonia gas, nitrogen gas, or both can be used as the source for the second dopant.

As the carrier gas, for example, such an inert gas as argon, hydrogen gas, nitrogen gas, or the like is used.

No particular limitation is imposed on the proportion of the gas included in the raw material gas as long as the amount of the first dopant included in the SiC film is in a range of from 10 atomic concentration in ppm through 10 atomic concentration in % or is in a range of more than 10 atomic concentration in % and 30 atomic concentration in % or less.

For example, 0.01≤Y/X≤0.5 may be true, where X denotes a flow rate (sccm) of the Si source included in the raw material gas and Y denotes a flow rate (sccm) of the source for the first dopant.

No particular limitation is imposed on the flow rate of the source for the second dopant as long as the electrical resistivity of a SiC film obtained is controlled in a desired range.

For example, 0.01≤Z/X≤10 may be true, where X denotes a flow rate (sccm) of the Si source included in the raw material gas and Z denotes a flow rate (sccm) of the source for the second dopant.

By supplying the raw material gas, it is possible to form, on the substrate, a SiC film including the first dopant (and the second dopant, if necessary).

The film-forming temperature is, for example, in a range of from 1,050° C. through 1,700° C., preferably in a range of from 1,150° C. through 1,650° C., more preferably from 1,200° C. through 1,600° C., still more preferably from 1,250° C. through 1,550° C., and even more preferably from 1,350° C. through 1,500° C.

The film-forming rate is, for example, in a range of from 0.01 mm/h through 3 mm/h, preferably in a range of from 0.1 mm/h through 2 mm/h, and more preferably from 0.5 mm/h through 1.6 mm/h. When the film-forming rate is 0.01 mm/h or more, it is possible to sufficiently shorten a takt time. When the film-forming rate is 3 mm/h or less, the density of the SiC film is sufficiently increased.

However, the film-forming temperature and the film-forming rate change in accordance with the temperature and the pressure of the gas used.

After step S120, the polycrystalline SiC film can be obtained on the substrate.

### (Step S130)

Next, if necessary, the substrate is removed, and only the SiC film is recovered.

No particular limitation is imposed on the method for removing the substrate. For example, the substrate may be removed through mechanical polishing.

If necessary, the thickness of the SiC film may be appropriately adjusted by polishing the surface of the SiC film.

Through the above steps, the component according to one embodiment of the present disclosure can be produced.

Note that, the above description is merely one example, and the component according to one embodiment of the present disclosure may be produced by a different method as long as the SiC film produced through CVD is formed.

### EXAMPLES

Hereinafter, examples of the present disclosure will be described. Note in the following that, Examples 1 to 16 are Working Examples, and Examples 21 to 25 are Comparative Examples.

### Example 1

A SiC film was formed on a substrate in the following manner.

First, the substrate was disposed in a reaction chamber having an internal volume of 100 L.

As the substrate, a graphite plate of 10 mm long×10 mm wide×2 mm thick was used. One of the 10 mm×10 mm surfaces was used as a film-forming surface. The impurity content of this graphite plate was 20 ppm, the coefficient of linear thermal expansion thereof was 5.6/K, and the density thereof was 1.82 g/cm³.

Next, air in the reaction chamber was removed through vacuuming, and the internal pressure of the chamber was 10 Pa. Subsequently, the internal pressure of the chamber was adjusted by H₂ gas to 13,000 Pa. Subsequently, the substrate was heated to 1,450° C. through conduction of electricity. In this state, a gas mixture was supplied into the reaction chamber, and formation of a SiC film through CVD was performed at 13,000 Pa.

The supplied gas was a gas mixture including SiCl₄ (150 sccm), CH₄ (75 sccm), AlCl₃ (15.0 sccm), and H₂ (400 sccm). Of these, the H₂ gas was a carrier gas.

The target thickness of the SiC film was from about 0.5 mm through about 1 mm. Note that, the thickness of the SiC film can be adjusted by the film-forming time.

The obtained SiC film-including substrate is referred to as “Sample 1”.

### Example 2

In the same manner as in Example 1, a SiC film was formed on the substrate.

In Example 2, the flow rate of AlCl₃ included in the gas mixture was 25.0 sccm. The obtained SiC film-including substrate is referred to as “Sample 2”.

### Example 3

In the same manner as in Example 1, a SiC film was formed on the substrate.

In Example 3, the supplied gas was a gas mixture including SiCl₄ (150 sccm), CH₄ (75 sccm), AlCl₃ (10.0 sccm), N₂ (30 sccm), and H₂ (400 sccm). The obtained SiC film-including substrate is referred to as “Sample 3”.

### Examples 4 to 6

In the same manner as in Example 3, a SiC film was formed on the substrate.

In Examples 4 to 6, the gas compositions of the gas mixtures were different from the gas composition of the gas mixture in Example 3. The obtained SiC film-including substrates are referred to as “Sample 4” to “Sample 6”.

### Example 7

A SiC film was formed on a substrate in the following manner.

First, the substrate was disposed in a reaction chamber having an internal volume of 100 L.

As the substrate, a graphite plate of 20 mm long×20 mm wide×1 mm thick was used. One of the 20 mm×20 mm surfaces was used as a film-forming surface. The impurity content of this graphite plate was 20 ppm, the coefficient of linear thermal expansion thereof was 5.6/K, and the density thereof was 1.82 g/cm³.

Next, air in the reaction chamber was removed through vacuuming, and the internal pressure of the chamber was 10 Pa. Subsequently, the internal pressure of the chamber was adjusted by H₂ gas to 1,000 Pa. Subsequently, the substrate was heated to 1,200° C. In this state, a gas mixture was supplied into the reaction chamber, and formation of a SiC film through CVD was performed at 1,000 Pa.

The supplied gas was a gas mixture including CVD-4000 (172 sccm), Al(CH₃)₃ (1 sccm), and H₂ (120 sccm). Of these, the H₂ gas was a carrier gas.

When CVD-4000 and Al(CH₃)₃ are used as the Si source, the C source, and the Al source, doping with Al is readily performed from the viewpoint of thermodynamics compared to use of SiCl₄, CH₄, and AlCl₃ as in Examples 1 to 6.

The target thickness of the SiC film was from about 0.3 mm through about 0.7 mm. Note that, the thickness of the SiC film can be adjusted by the film-forming time.

The obtained SiC film-including substrate is referred to as “Sample 7”.

### Examples 8 to 16

In the same manner as in Example 7, a SiC film was formed on the substrate.

In Examples 8 to 16, the gas compositions of the gas mixtures were different from the gas composition of the gas mixture in Example 7. The obtained SiC film-including substrates are referred to as “Sample 8” to “Sample 16”.

### Example 21

In the same manner as in Example 1, a SiC film was formed on the substrate. In Example 21, a gas mixture the same as the gas mixture in Example 1 except for including no AlCl₃, was used.

The obtained SiC film-including substrate is referred to as “Sample 21”.

### Example 22

In the same manner as in Example 21, a SiC film was formed on the substrate. In Example 22, a gas mixture the same as the gas mixture in Example 21 except for further including N₂ (100 sccm), was supplied.

The obtained SiC film-including substrate is referred to as “Sample 22”.

### Example 23

A sample was produced through ion implantation of Al into the surface of a commercially available single crystal SiC plate (4H). Conditions for implantation are as follows:
Species of ion: Al,
Valency: divalent,
Acceleration energy: 600 keV,
Dosing amount: 2.0×10¹⁶ atoms/cm², and
Implantation temperature: room temperature.

The obtained sample is referred to as “Sample 23”.

### Examples 24 and 25

In the same manner as in Example 7, a SiC film was formed on the substrate. In Examples 24 and 25, a gas mixture the same as the gas mixture in Example 1 except for including no Al(CH₃)₃, was used.

The obtained SiC film-including substrates are referred to as “Sample 24” and “Sample 25”.

Tables 2 and 3 below collectively show the supplied gases used for film formation through CVD in the samples, and the thicknesses of the obtained SiC films.

TABLE 2

| | | | | | | Thickness |
|---|---|---|---|---|---|---|
| | Gas mixture | | | | | of SiC |
| | SiCl₄ | CH₄ | AlCl₃ | N₂ | H₂ | film |
| Samples | (scan) | (sccm) | (sccm) | (sccm) | (sccm) | (μm) |
| 1 | 150 | 75 | 15.0 | 0 | 400 | 562 |
| 2 | 150 | 75 | 25.0 | 0 | 400 | 755 |
| 3 | 150 | 75 | 10.0 | 30 | 400 | 730 |
| 4 | 150 | 75 | 41.7 | 50 | 400 | 687 |
| 5 | 150 | 75 | 50.0 | 50 | 400 | 669 |
| 6 | 150 | 120 | 50.0 | 50 | 400 | 713 |
| 21 | 150 | 75 | 0 | 0 | 400 | 463 |
| 22 | 150 | 75 | 0 | 100 | 400 | 531 |
| 23 | — | — | — | — | — | (380) |

TABLE 3

| | Gas mixture | | | Thickness |
|---|---|---|---|---|
| | CVD-4000 | Al(CH₃)₃ | H₂ | of SiC film |
| Samples | (sccm) | (sccm) | (sccm) | (μm) |
| 7 | 172 | 1 | 120 | 468 |
| 8 | 165 | 2 | 120 | 392 |
| 9 | 99 | 5 | 120 | 309 |
| 10 | 136 | 10 | 50 | 293 |
| 11 | 102 | 10 | 120 | 569 |
| 12 | 95 | 8 | 110 | 522 |
| 13 | 155 | 10 | 100 | 583 |
| 14 | 66 | 11 | 110 | 410 |
| 15 | 66 | 10 | 120 | 448 |
| 16 | 62 | 20 | 120 | 371 |
| 24 | 185 | 0 | 120 | 468 |
| 25 | 47 | 0 | 420 | 685 |

Note that, in the samples (excluding Sample 23), the thickness of the SiC film was defined as an average of randomly selected three points thereof. Meanwhile, in Sample 23, a value of the maximum permeation depth of Al from the surface was described in the corresponding cell in the column of “Thickness of SiC film”.

### Evaluation

The following evaluations were performed using each of the samples.

### (Evaluation of Density)

The substrate alone was removed from the sample through mechanical polishing, and the density of the obtained SiC was measured by the Archimedes method. The densities of Samples 1 to 6, 21, and 22 were all 3.2 g/cm³.

### (Evaluation of Al Doping Amount)

The samples were evaluated through electron probe microanalysis (EPMA) for the doping amount of Al included in the SiC film. Mirror polishing was performed to the surface of the SiC film of the sample. Ten points thereof were measured by moving the measurement point at 100 μm intervals on a straight line passing through the center of the surface, followed by calculating an average value thereof.

No particular limitation is imposed on the measurement method of the doping amount, and SEM-EDX or SIMS may be used or ICP-AES or ICP-MS may be used. When ICP-AES or ICP-MS is used, quantitative analysis can be performed by milling the sample and then immersing the resulting sample in acid.

The Al doping amount in Sample 23 was evaluated through EPMA line analysis in a cross section of Sample 23. In the analysis results, the maximum Al concentration obtained in a range of from the surface through 1 μm in depth was defined as the Al doping amount.

### (Evaluation of Plasma Resistance)

An etching test was performed using the sample. The plasma resistance of the sample was evaluated from the obtained results.

The etching test was performed in the following manner.

First, mirror polishing was performed to the surface of the SiC film of the sample. For Samples 7 to 16, 24, and 25, mirror polishing was also performed to lateral surfaces of the sample. Next, a piece of KAPTON tape 0.1 mm thick (P-222: obtained from Nitto Denko Corporation) was placed on a part of the mirror-polished surface of the SiC film, thereby forming a masked region and a mask-free region on the SiC film. In order to minimize the influence of the KAPTON tape, the area ratio between the masked region and the mask-free region was set to 1:8. The lateral surfaces of the sample were not subjected to masking.

For Sample 23, the masked region and the mask-free region were formed on the Al-implanted surface.

Next, the resulting sample was disposed on a stage of an etching apparatus (EXAM: obtained from SHINKO SEIKI CO., LTD.) with the SiC film (the Al-implanted surface for Sample 23) facing upward, followed by performing the etching test.

Testing conditions were the following two different conditions.

### (Test 1)

CF₄ flow rate: 100 sccm,
Pressure: 10 Pa,
Power: 350 W,
Testing time: 65 minutes,
Stage temperature: 20° C.

### (Test 2)

CF₄ flow rate: 10 sccm,
O₂ flow rate: 10 sccm,
Ar flow rate: 90 sccm,
Pressure: 10 Pa,
Power: 350 W,
Testing time: 65 minutes,
Stage temperature: 20° C.

Note that, Test 2 was only performed to Examples 7 to 16, and 25.

After the test, an etching amount was calculated from the difference (Δt) in the thickness of the SiC film between the masked region and the mask-free region. The smaller the etching amount, the higher the etching resistance of the SiC film, i.e., the higher the plasma resistance of the SiC film. The Δt can be varied in accordance with plasma etching testing conditions employed. However, under the present testing conditions, the Δt was in the range of 2.5 μm≤Δt≤5.0 μm.

Table 4 below collectively shows the evaluation results obtained in the samples.

TABLE 4

| | | Test 1 | | Test 2 | |
|---|---|---|---|---|---|
| | Al doping | Etching | Relative | Etching | Relative |
| | amount | amount | etching | amount | etching |
| Samples | (atom %) | (nm) | amount | (nm) | amount |
| 1 | 0.044 | 4015 | 0.88 | | |
| 2 | 0.071 | 3194 | 0.70 | | |
| 3 | 0.035 | 3331 | 0.73 | | |
| 4 | 0.11 | 3148 | 0.69 | | |
| 5 | 0.13 | 3057 | 0.67 | | |
| 6 | 0.14 | 2555 | 0.56 | | |
| 7 | 0.4 | 3952 | 0.87 | 8656.19 | 0.75 |
| 8 | 1.5 | 4263 | 0.93 | 7969.00 | 0.69 |
| 9 | 5.5 | 3549 | 0.78 | 2442.41 | 0.21 |
| 10 | 6.8 | 2190 | 0.56 | 2749.50 | 0.24 |
| 11 | 9.9 | 2204 | 0.48 | 2252.79 | 0.20 |
| 12 | 11.6 | 1710 | 0.44 | 1916.09 | 0.17 |
| 13 | 14.8 | 833 | 0.21 | 1384.50 | 0.12 |
| 14 | 16.1 | 1508 | 0.39 | 1793.42 | 0.16 |
| 15 | 21.7 | 1255 | 0.32 | 1172.36 | 0.10 |
| 16 | 27.3 | 1203 | 0.31 | 1176.50 | 0.10 |
| 21 | 0 | 4563 | 1.00 | | |
| 22 | 0 | 4472 | 0.98 | | |
| 23 | 1 | 4107 | 0.90 | | |
| 24 | 0 | 4672 | 1.04 | | |
| 25 | 0 | 4611 | 1.01 | 11508.44 | 1.00 |

In Test 1, the etching amounts of the samples were shown as relative values to the etching amount of Sample 21. In Test 2, the etching amounts of the samples were shown as relative values to the etching amount of Sample 25. The smaller the values in these columns, the higher the plasma resistance of the samples.

These results indicate that the plasma resistance is not so high in Samples 21, 22, 24, and 25, in which the SiC film was not doped with Al. Also, the plasma resistance is not so high in Sample 23 including SiC produced through ion implantation rather than CVD.

Especially, for Sample 23, the maximum doping concentration was about 1%, but the doping range of Al was only a region 1 μm or less in depth from the surface. A coefficient of thermal diffusion of Al is very low, i.e., about 8×10⁻¹⁴ cm²/s (c-axis direction) and doping cannot be performed over the entire sample through ion implantation. It is therefore considered that because the Al-undoped region is also etched during the test, the effect of increasing the plasma resistance could not sufficiently be obtained. Also, once etching has reached a region 1 μm or more in depth from the surface, the etching rate significantly increases. It is therefore expected that as the testing time of the etching test becomes longer, reduction in the plasma resistance of Sample 23 becomes more significant than in Samples 1 to 10. This suggests that in-situ doping using CVD is preferable to ion implantation as a method of introducing Al for increasing the plasma resistance.

Meanwhile, Samples 1 to 16 including the Al-doped SiC film produced through CVD are all found to exhibit high plasma resistance.

In Test 1, comparison among Samples 1 to 6 indicates a general tendency that the more the Al doping amount, the higher the plasma resistance.

In Test 1 and Test 2, comparison among Samples 7 to 10 also indicates a general tendency that the more the Al doping amount, the higher the plasma resistance.

In Test 1 (the etching gas was CF₄), however, the highest plasma resistance could be achieved in Sample 13, in which the Al doping amount was 14.8%. In Samples 14 to 16, in which the Al doping amount was more than 14.8%, the effect of increasing the plasma resistance tended to be slightly lost, but still the plasma resistance was high.

Meanwhile, in Test 2 (the etching gas was a gas mixture of CF₄, O₂, and Ar), there was a tendency that the more the Al doping amount, the higher the plasma resistance.

The above suggests a general tendency that the more the Al doping amount, the higher the plasma resistance, although the plasma resistance of the Al-doped SiC film produced through CVD may be greatly varied with the type of an etching gas.

Comparison among Samples 1 to 16 does not always demonstrate that the more the Al doping amount, the higher the plasma resistance. This is because the group of Samples 1 to 6 and the group of Samples 7 to 16 are different in the states of the samples.

The Si source supply gas, the C source supply gas, and the Al source supply gas used upon the formation of the SiC film were SiCl₄, CH₄, and AlCl₃ in Samples 1 to 6 and were CVD-4000 and Al(CH₃)₃ in Samples 7 to 10. As described above, doping with Al is more readily performed from the viewpoint of thermodynamics in Samples 7 to 10, and most of Al(CH₃)₃ is consumed during the formation of the SiC film, while doping with only a small amount of Al is performed in Samples 1 to 6, and unreacted AlCl₃ tends to remain during the formation of the SiC film. Although such remaining AlCl₃ can be removed through mirror polishing, only the front surface of the SiC film is mirror-polished in Samples 1 to 6 and AlCl₃ remains on the lateral surfaces of the samples.

In Samples 1 to 6 that were subjected to the etching test in a state where AlCl₃ remained on the lateral surfaces of the samples, AlCl₃ is attached to the front surface of the SiC film through dusting or the like upon etching. The attached AlCl₃ produces the effect of reducing the etching amount. This is a conceivable reason why Samples 1 to 6 exhibited plasma resistance higher than expected.

Meanwhile, in Samples 7 to 10 in which the amount of the remaining unreacted Al(CH₃)₃ was small and mirror polishing was performed to the lateral surfaces of the samples, the above-described phenomenon did not occur. This is a conceivable reason why Samples 7 to 10 appeared to exhibit the same degree of plasma resistance as the plasma resistance of Samples 1 to 6 although the Al doping amount is more than in Samples 1 to 6.

All in all, the increase in etching resistance caused by Al doping is common among Samples 1 to 10.

In this way, it was confirmed that the plasma resistance was increased by Al-doping the SiC film produced through CVD.

The present disclosure can provide a semiconductor production apparatus component having plasma resistance that is significantly higher than the plasma resistance of existing components. Also, the present disclosure can provide a method for producing such a component.

What is claimed is:

1. A component for a semiconductor production apparatus, the component comprising:
a part of polycrystalline silicon carbide (SiC) produced through chemical vapor deposition (CVD), the part being of the component, wherein
the part of the polycrystalline SiC includes a first dopant with which the part of the polycrystalline SiC is doped in a range of from 10 atomic concentration in ppm through 10 atomic concentration in % with respect to an entirety of the part or in a range of more than 10 atomic concentration in % and 30 atomic concentration in % or less with respect to the entirety of the part, and
the first dopant includes at least one element selected from the group consisting of aluminum (Al), yttrium (Y), magnesium (Mg), tin (Sn), calcium (Ca), zinc (Zn), cobalt (Co), iron (Fe), nickel (Ni), silver (Ag), and chromium (Cr).

2. The component according to claim 1, wherein
the part further includes a second dopant with which SiC is doped, and
the second dopant includes at least one element selected from the group consisting of boron (B) and nitrogen (N).

3. The component according to claim 2, wherein
the second dopant is N.

4. The component according to claim 1, wherein
the first dopant is Al.

5. The component according to claim 1, further comprising:
a substrate, wherein
the part is a film on the substrate.

6. The component according to claim 1, wherein
the component consists of the part.

7. The component according to claim 1, wherein
the component is an edge ring, an electrostatic chuck, or a shower plate that are for a plasma etching apparatus, or is a protective cover of a sensor in a chamber of the plasma etching apparatus.

8. A method for producing a component for a semiconductor production apparatus, the method comprising:
supplying a gas mixture to a surface of a substrate, the gas mixture including a Si source gas, a C source gas, and a source gas for a first dopant, thereby forming a film of polycrystalline SiC through chemical vapor deposition (CVD), the film of the polycrystalline SiC being doped with the first dopant in a range of from 10 atomic concentration in ppm through 10 atomic concentration in % or in a range of more than 10 atomic concentration in % and 30 atomic concentration in % or less, wherein
the first dopant includes at least one element selected from the group consisting of aluminum (Al), yttrium (Y), magnesium (Mg), tin (Sn), calcium (Ca), zinc (Zn), cobalt (Co), iron (Fe), nickel (Ni), silver (Ag), and chromium (Cr).

9. The method according to claim 8, wherein
the first dopant is Al, and
the source gas for the first dopant includes at least one selected from the group consisting of aluminum halides and organic aluminum compounds.

10. The method according to claim 8, wherein
the gas mixture further includes a source gas for a second dopant, and
the second dopant includes at least one element selected from the group consisting of boron (B) and nitrogen (N).

11. The method according to claim 10, wherein
the second dopant is N, and
the source gas for the second dopant includes at least one selected from the group consisting of ammonia gas and nitrogen gas.

12. The method according to claim 8, wherein
the Si source gas includes at least one selected from the group consisting of SiCl₄, SiHCl₃, SiH₂Cl₂, and SiH₄.

13. The method according to claim 8, wherein
the C source gas includes at least one selected from the group consisting of CH₄, C₂H₆, and C₃H₈.

14. The method according to claim 8, wherein
the Si source gas and the C source gas are a single gas, and the single gas includes at least one selected from the group consisting of CH₃SiCl₃, (CH₃)₂SiCl₂, and (CH₃)₃SiCl.
